(19) United States
(12) Patent Application Publication
(10) Pub. No.: US 2004/0251527 A1
(43) Pub. Date: Dec. 16, 2004

(54) Intermediate support for electronic components and method for solder contacting such an intermediate support

(76) Inventors: Jozef Van Puymbroeck, Oostkamp (BE); Marcel Heerman, Merelbeke (BE)

Correspondence Address: HARNESS, DICKEY & PIERCE, P.L.C., P.O.BOX 8910, RESTON, VA, 20195, US

(21) Appl. No.: 10/489,592

(22) PCT Filed: Sep. 13, 2002
(86) PCT No.: PCT/DE02/03429

(30) Foreign Application Priority Data
Sep. 14, 2001 (DE) 10145348.5

(51) Int. Cl. H01L 23/02

(52) U.S. Cl. 257/678

(57) ABSTRACT

The invention relates to an intermediate support for electronic components, for example a semiconductor, comprising a plastic substrate with contact bumps (2) in one-piece, covered with a metallic layer, which is electrically connected to at least one conducting path of said substrate (1). Said contact bumps (2) each comprise a well wettable path, extending from the tips to the base thereof and each leading to the corresponding contact bump (2) base in a solder receiving region with suction (11). Therefore, by soldering said contact bumps, excess solder can be sucked off, such that short circuits can be avoided even without the use of a solder resist. By solder contacting said intermediate support, the solder can thus be applied over a large surface on a circuit support and sucked off the cavities between the contact points by reflow soldering.

This application is the national phase under 35 U.S.C. § 371 of PCT International Application No. PCT/DE02/03429 which has an International filing date of Sep. 13, 2002, which designated the United States of America and which claims priority on German Patent Application number DE 101 45 348.5 filed Sep. 14, 2001, the entire contents of which is hereby incorporated herein by reference.

### FIELD OF THE INVENTION

The invention generally relates to an intermediate substrate or support for electronic components. Preferably, it relates to one having a substrate base made of plastic on whose surface are formed integral contact studs or bumps, with the surface of each of these studs being provided at least partially with a solderable metal layer that is electrically connected to at least one conducting track of the substrate base. In addition, the invention generally relates to a method for solder bonding such an intermediate substrate.

### BACKGROUND OF THE INVENTION

An intermediate substrate is known from EP 971 405 A2 for example. These intermediate substrates, also referred to as a PSGA (Polymer Stud Grid Array), are used for lead bonding of semiconductor chips on printed circuit boards for example. Their use is not limited to semiconductor components, however; such intermediate substrates can also be used for providing contacts to other electronic components.

The intermediate substrates themselves are normally fabricated by injection molding, as described in EP 971 405 A2, with the contact studs being formed in the process, although these contact studs can also be formed using other techniques, for instance by hot-pressing of foils, where all types of plastics, thermoplastics, duroplastics and even epoxy resins can be used. The contact studs on the intermediate substrates can be used both for bonding a semiconductor chip or other component on the intermediate substrate and for bonding the intermediate substrate on a printed circuit board.

Constant advances in miniaturization of soldered connections for ever greater component packing densities is limited by the accuracy with which the solder paste can be applied to each of the contact points of a printed circuit board or component. In order to avoid short-circuits between the solder points, it has been necessary until now to separate these contact points on the connecting substrate by use of solder resist. This solder resist can only be applied with a limited accuracy, however, which then limits both the miniaturization and the fabrication yield.

The geometries of the circuits, the solder resist and the solder paste must be aligned very accurately with each other, but the unavoidable tolerances associated with each of these three elements are still summed together. In particular, it is very difficult to apply the solder paste to precisely defined points. Once a short-circuit has occurred in the bonding of a component, however, there is no way of rectifying this fault because the component can no longer be separated from the connection substrate.

### SUMMARY OF THE INVENTION

An object of an embodiment of the invention is thus to define an intermediate substrate, and a method for solder bonding such an intermediate substrate, where the demands placed on applying the solder are less high than in methods of a prior art, wherein a higher reliability of the soldered connections against short-circuits is achieved.

An object is achieved according to an embodiment of the invention by an intermediate substrate wherein the contact studs have, from their tip to their base, an easily wettable path for guiding liquid solder. Further, solder-receiving areas having a capillary action are preferably formed in the base area of each of the contact studs, presenting a wetting barrier with respect to each adjacent contact stud.

By suitable geometric design and surface-coating of the contact studs and their surrounding areas, the intermediate substrate has been designed according to an embodiment of the invention, to provide an additional function that enables excess solder to be drawn off from the actual contact points. The good wettability of the outer surfaces of the contact studs indicates that the excess solder is guided and drawn away to the base areas of these contact studs, where it is held in receiving areas provided for the purpose, so that it cannot cause any damaging short-circuit effects.

As such, the application of the solder is far less critical than in traditional arrangements and methods. This is because the excess solder can no longer create a short-circuit with the adjacent contact, but is drawn off into safe areas. Further, the solder no longer needs to be applied with high accuracy as dots of solder solely on the contact surfaces or contact elements, but can be distributed in a far simpler way in a continuous layer over all contact points, since the areas between the contact points are then sucked clear during reflow soldering. Of course, the amount of solder applied as a continuous layer must be set to suit the solder-holding capacity of the solder receiving areas on the contact studs.

Thus, using the intermediate substrate according to an embodiment of the invention, shorter distances between the contact points can also be realized. As such, the overall packing density can be increased. Another advantage is that, owing to the selective drawing off of the solder, an additional self-alignment of the contact studs with a circuit substrate takes place. This thereby increases the positioning accuracy of components, which is a major advantage for bonding optical components for example.

In an advantageous embodiment, the solder-receiving areas to be provided according to an embodiment of the invention on the contact studs can be formed as recesses in the surface of the substrate base in the base areas of the contact studs, where they can surround to a greater or lesser extent in the form of a continuous or partial annular groove the base area of the contact stud. It is also possible, however, that the recesses each extend asymmetrically away from the base area of a contact stud. Thus, if the solder receiving areas of adjacent contact studs are arranged in an opposite direction, then the distances between the contact studs can be made particularly small. An embodiment of the invention can be applied particularly advantageously to flip-chip assembly of semiconductor components.

In another advantageous embodiment of the invention, the solder receiving areas can also be formed as capillary channels in the contact studs themselves. For instance, indentations shaped as slots or crosses can be formed in the longitudinal direction of the contact studs as capillary channels that either act themselves directly as solder receiving areas, or by way of their capillary action lead the excess solder to a recess additionally arranged in the surface of the substrate base.

The solder-guiding paths on the contact studs can be formed by a metallization with suitable, easily wettable materials. The wetting and capillary action can be enhanced, however, by grooves or channels made on the surface or inside the contact studs as already mentioned above. It is even conceivable, for example, to make all or part of the outer perimeter of the contact studs fluted.

A method according to an embodiment of the invention for solder bonding of such an intermediate substrate on a circuit substrate having flat contact elements arranged on its upper face includes the following steps:

covering the contact elements on the upper face of the circuit substrate with a continuous solder layer;

placing the intermediate substrate on the circuit substrate in such a way that its contact studs each lie above associated contact elements, on the solder layer, and

liquefying the solder layer by heating, whereby a solder connection is formed between each instance of a contact element and a contact stud, and whereby excess solder is drawn out of the areas between the contact elements via the contact studs into the solder receiving areas.

### BRIEF DESCRIPTION OF THE DRAWINGS

Further advantages, features and details of the invention will become evident from the description of illustrated embodiments given hereinbelow and the accompanying drawings, which are given by way of illustration only and thus are not limitative of the present invention, wherein:

FIG. 1 shows the arrangement of an intermediate substrate on a semiconductor component prepared for solder bonding,

FIG. 2 shows the arrangement of FIG. 1 during soldering and

FIG. 3 shows the intermediate substrate and the component of FIG. 1 after the solder process;

FIG. 4 shows a sectional detail IV-IV from FIG. 1,

FIG. 5 shows a sectional view corresponding to FIG. 4 of a modified embodiment of an intermediate substrate,

FIGS. 6 to 8 show an intermediate substrate modified with respect to FIG. 1 in the same stages as those of FIGS. 1 to 3,

FIG. 9 shows a sectional detail IX-IX from FIG. 8, and

FIG. 10 shows a perspective sectional view of an intermediate substrate as shown in FIG. 1.

### DETAILED DESCRIPTION OF THE PREFERRED EMBODIMENTS

The intermediate substrate 1 shown in FIGS. 1 to 3 is made of a plastic material and on its lower face has integral contact studs 2 for bonding to flat contact elements 3 of a circuit substrate, in this example a semiconductor chip 4. Thus this case concerns what is known as flip-chip assembly of an unpackaged semiconductor. After being connected to the semiconductor 4, the intermediate substrate 1, only a section of which is shown, is bonded for example onto another circuit substrate such as a circuit board. This bonding of the intermediate substrate can be made using connecting elements not shown, for instance traditional connecting elements or even additional contact studs, whereby these additional contact studs can be provided either on the same face beside the semiconductor element 4 or on the opposite face of the intermediate substrate in a way that is not shown.

The more detailed structure of the intermediate substrate 1 is shown schematically in perspective in a cross-sectional diagram in FIG. 10. Here the contact studs 2 are each surrounded by annular recesses 11 that exhibit a capillary action for liquid solder when it reaches the base 2c of the contact studs via the tips 2a and the easily wettable circumferential faces 2b of the contact studs owing to its surface tension. The contact studs are provided with a partial or complete metal coating 12 that extends over the circumferential face into the corresponding recess 11 and over the outer edge of the recess to a conducting track 13 on the surface of the intermediate substrate 1. In this way, the contact studs are electrically connected to the required conducting tracks of the intermediate substrate. The outer edge of the recess 11 acts in each case as a wetting barrier or capillary barrier, so that the solder drawn into the recess cannot escape over the edge, and above all cannot form a short-circuit across the insulating gap 14 between the individual contact studs. The conducting tracks 13 shown in FIG. 10 are only suggested by way of example; the electrical connections can be formed in any way of course. In particular, conducting connections—also not shown—can lead via edge regions of the intermediate substrate or via holes to the opposite surface and to conducting tracks or components arranged there.

The enlarged sectional view in FIG. 4 shows in plan view two adjacent contact studs with grid spacing d1 that are each surrounded by circular recesses 11. FIG. 5 shows a modification of this in which each of the circular recesses has been replaced by recesses 16 extending on one side in opposite directions. In this way, the contact studs 2 can be positioned closer to each other with a smaller grid spacing d2.

The bonding method can be followed from FIGS. 1 to 3. In the diagram shown in FIG. 1, the circuit substrate 4 is covered in the area of the connecting elements 3 with a continuous solder layer 5 extending continuously over all the contact elements 3. The intermediate substrate 1 is then placed on it and positioned by using alignment studs 6, where positioning pegs 7 engage in positioning holes 8 in the circuit substrate 4. Of course, the reverse arrangement with positioning pegs and positioning holes located in the respectively opposite part is also possible.

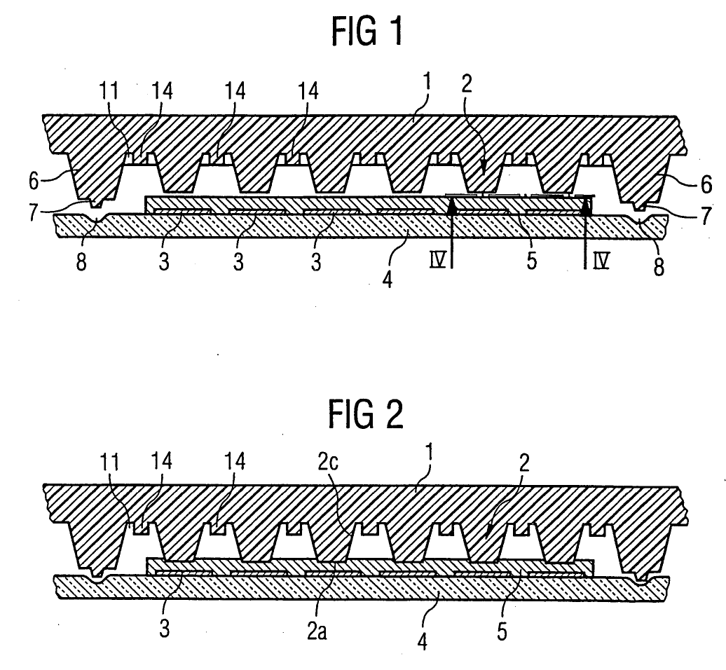

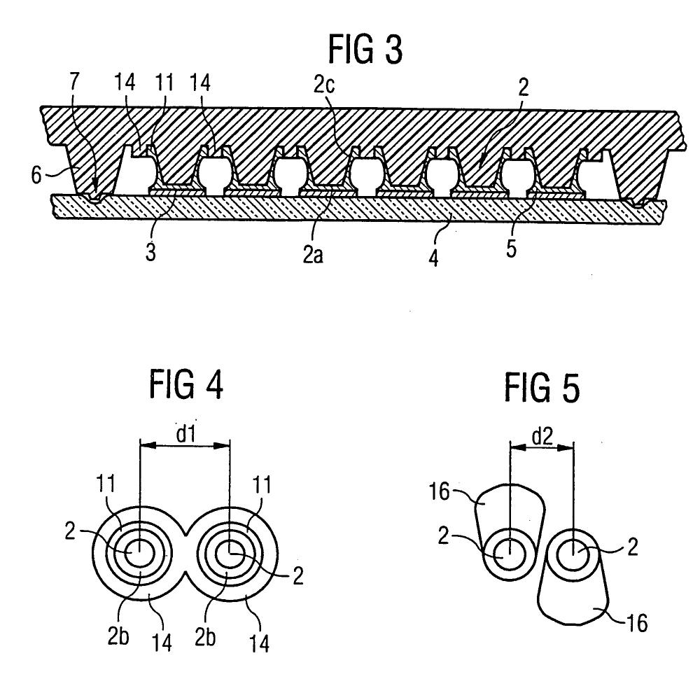

As shown in FIG. 2, the solder 5 is liquefied, so that the tips 2a of the contact studs 2 dip into the liquid solder layer. In the process, the excess solder between the individual contact elements 3 is drawn up to the bases 2c of the respective contact studs and deposited in the recesses 11 by the guiding over the surface and the wetting of the contact studs. Thus no excess solder remains between the contact studs 2 and between the contact elements 3, so that there is also no short-circuit risk. Thus when the solder solidifies, only the contact studs 2 are connected to the contact elements 3 as shown in FIG. 3, while the excess solder is located on the circumferential faces of the contact studs 2 and in the recesses 11.

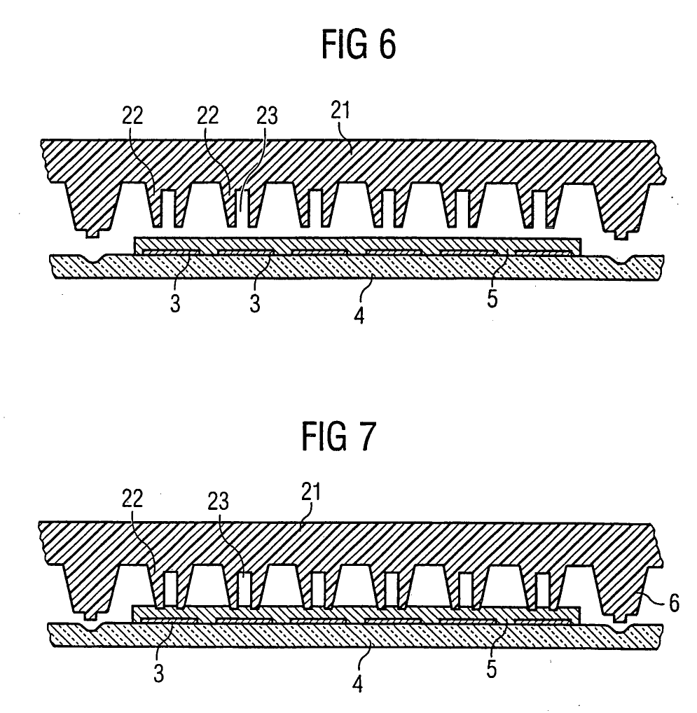

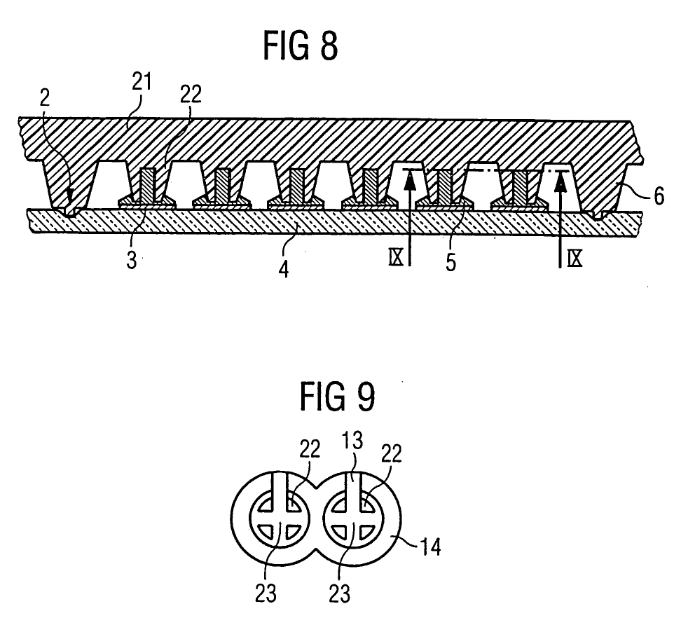

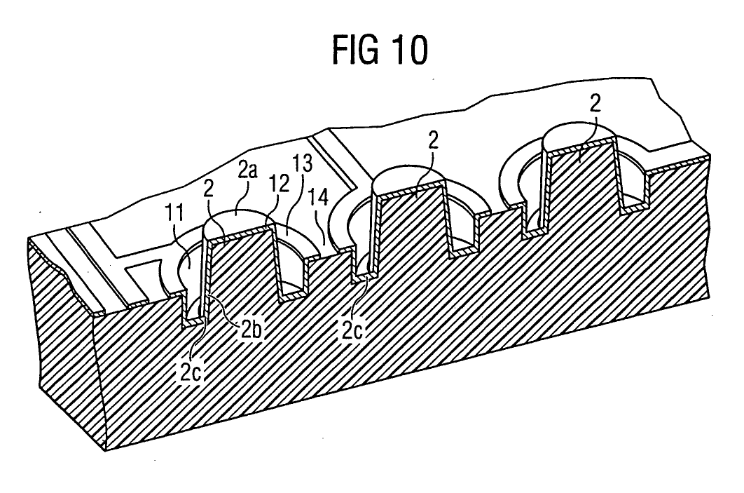

The same process is described in FIGS. 6 to 9 with reference to a modified intermediate substrate 21. This intermediate substrate 21 has contact studs 22 that have cross-shaped slots 23 running through their length. Otherwise, the intermediate substrate 21 has exactly the same design as the intermediate substrate 1. In the same way as this, it is also placed on a circuit substrate 4 and soldered to it. The process is completed in the same way as already described with reference to FIGS. 1 to 3. The sole difference is that the excess solder is not drawn over the outer surfaces of the contact studs into additional recesses of the intermediate substrate, but this excess solder is drawn directly into the cross-shaped slots 23 acting as solder receiving areas. Of course additional recesses can be provided in the intermediate substrate 21 in this case as well.

Exemplary embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. An intermediate substrate for electronic components, comprising:
a substrate base made of plastic; and
integral contact studs, formed on a surface of the substrate base, a surface of each of the studs being provided at least partially with a solderable metal layer connected to at least one conducting track of the substrate base, wherein
the contact studs include an easily wettable path for guiding liquid solder, and wherein solder-receiving areas having a capillary action are formed in a base area of each of the contact studs, presenting a wetting barrier with respect to each adjacent contact stud.

2. The intermediate substrate as claimed in claim 1, wherein
the solder-receiving areas are each formed as recesses in the surface of the substrate base in the base area of the contact studs.

3. The intermediate substrate as claimed in claim 2, wherein
the recesses at least partially surround, in the form of an annular groove, the contact studs in their base area.

4. The intermediate substrate as claimed in claim 2, wherein
the recesses each extend asymmetrically away from the base area of a contact stud.

5. The intermediate substrate as claimed in claim 1, wherein
the solder receiving areas are formed as capillary channels in the contact studs.

6. The intermediate substrate as claimed in claim 1, wherein
the solder-guiding paths on the contact studs are formed by an easily wettable metallization of the surface of the contact studs.

7. The intermediate substrate as claimed in claim 1, wherein
the solder-guiding paths are formed by capillary channels, made at least one of on the surface and inside the contact studs.

8. The intermediate substrate as claimed in claim 7, wherein
the contact studs are fluted at least over part of a circumferential face of the contact studs.

9. A method for solder bonding an intermediate substrate on a circuit substrate having flat contact elements arranged on an upper face, the method comprising:
covering the contact elements on the upper face of the circuit substrate with a continuous solder layer;
placing the intermediate substrate on the circuit substrate in such a way that its contact studs of the intermediate substrate each lie above associated contact elements, on the solder layer; and
liquefying the solder layer by heating, whereby a solder connection is formed between each instance of a contact-element and a contact-stud, and whereby excess solder is drawn out of the areas between the contact elements via the contact studs into solder receiving areas.

10. The method as claimed in claim 9, wherein the intermediate substrate is placed and aligned on the circuit substrate by introducing positioning pegs into positioning holes.

11. The method as claimed in claim 9, wherein
a semiconductor component is used.

12. The method as claimed in claim 9, wherein
a circuit board is used as the circuit substrate.

13. The intermediate substrate as claimed in claim 3, wherein the recesses each extend asymmetrically away from the base area of a contact stud.

14. The intermediate substrate as claimed in claim 2, wherein the solder-guiding paths on the contact studs are formed by an easily wettable metallization of the surface of the contact studs.

15. The intermediate substrate as claimed in claim 2, wherein the solder-guiding paths are formed by capillary channels, made at least one of on the surface and inside the contact studs.

16. The method as claimed in claim 10, wherein a semiconductor component is used.

17. The method as claimed in claim 10, wherein a circuit board is used as the circuit substrate.

18. A method for solder bonding an intermediate support on a circuit substrate including contact elements, the method comprising:
covering the contact elements with a continuous solder layer;
aligning contact studs of the intermediate support with corresponding associated contact elements; and
liquefying the solder layer, whereby a solder connection is formed between each corresponding contact element and contact stud pair, and whereby excess solder is drawn out of areas between contact elements via the contact studs into solder receiving areas.

19. The method as claimed in claim 18, wherein the intermediate substrate is aligned on the circuit substrate using positioning pegs in positioning holes.

20. The method as claimed in claim 18, wherein a semiconductor component is used.

21. The method as claimed in claim 18, wherein a circuit board is used as the circuit substrate.

22. An intermediate support for electronic components, comprising:
a support base made of plastic; and
a plurality of contact bumps, formed on a surface of the support base, a surface of each of the bumps being provided at least partially with a solderable metal layer, wherein the contact studs include a wettable path for guiding liquid solder, and wherein solder-receiving areas are formed in a base area of the contact bumps.

23. The intermediate support of claim 22, wherein the solder-receiving areas form a wetting barrier with respect to each adjacent contact bump.

24. The intermediate support as claimed in claim 22, wherein the solder-receiving areas are each formed as recesses in the surface of the support base in the base area of the contact bumps.

25. The intermediate support as claimed in claim 24, wherein the recesses at least partially surround, in the form of an annular groove, the contact bumps in their base area.

26. The intermediate support as claimed in claim 24, wherein the recesses each extend asymmetrically away from the base area of a contact bump.

27. The intermediate support as claimed in claim 22, wherein the solder receiving areas are formed as capillary channels in the contact bumps.

28. The intermediate support as claimed in claim 22, wherein the solder-guiding paths on the contact bumps are formed by an easily wettable metallization of the surface of the contact bumps.

29. The intermediate support as claimed in claim 22, wherein the solder-guiding paths are formed by capillary channels, made at least one of on the surface and inside the contact bumps.

30. The intermediate support as claimed in claim 29, wherein the contact bumps are fluted at least over part of a circumferential face of the contact bumps.
